(19) United States
(12) Patent Application Publication
(10) Pub. No.: US 2024/0290762 A1
(43) Pub. Date: Aug. 29, 2024

(54) SEMICONDUCTOR PACKAGE

(71) Applicant: SAMSUNG ELECTRONICS CO., LTD., SUWON-SI (KR)

(72) Inventors: CHOONGBIN YIM, Suwon-si (KR); JONGKOOK KIM, Suwon-si (KR)

(21) Appl. No.: 18/519,211

(22) Filed: Nov. 27, 2023

(30) Foreign Application Priority Data
Feb. 27, 2023 (KR) 10-2023-0026121

(51) Int. Cl. H01L 25/10; H01L 23/31; H01L 23/538; H01L 25/065; H10B 80/00

(52) U.S. Cl. CPC H01L 25/105; H01L 23/3128; H01L 23/3135; H01L 23/5383; H01L 23/5384; H01L 23/5385; H01L 25/0655; H10B 80/00; H01L 24/08; H01L 24/16; H01L 24/32; H01L 24/73; H01L 2224/08235; H01L 2224/16227; H01L 2224/32225; H01L 2224/73204

(57) ABSTRACT

A semiconductor package includes a first redistribution substrate, a connection substrate on the first redistribution substrate, wherein the connection substrate includes an opening extending through the connection substrate, a chip structure including a first semiconductor chip in the opening and on the first redistribution substrate, a first interposer substrate including a through electrode extending through the first interposer substrate in the opening and on the first redistribution substrate, wherein the first interposer substrate is spaced apart from the chip structure, a second semiconductor chip on the first interposer substrate and electrically connected to the through electrode, a first molding layer on the chip structure, first interposer substrate, and second semiconductor chip, and a second redistribution substrate on the first molding layer and connection substrate, wherein a lower surface of the chip structure and the first interposer substrate are in electrical contact with an upper surface of the first redistribution substrate.

### CROSS-REFERENCE TO RELATED APPLICATIONS

This U.S. non-provisional patent application claims priority under 35 U.S.C.§ 119 to Korean Patent Application No. 10-2023-0026121, filed on Feb. 27, 2023, in the Korean Intellectual Property Office, the entire contents of which is hereby incorporated by reference.

### BACKGROUND OF THE INVENTION

The present disclosure relates to a semiconductor package, and more particularly, relates to a semiconductor package including a plurality of semiconductor chips.

High-performance, high-speed, and small electronic components have been increasingly demanded with the development of the electronics industry. To satisfy these demands, a packaging technique of providing a plurality of semiconductor chips in a single package has been suggested.

Recently, portable devices have been increasingly demanded in the electronics market, and thus small and light electronic components mounted in the electronics have been used. A semiconductor package technique of integrating a plurality of individual components in a single package as well as a technique of reducing a size of an individual component may be desirable to realize small and light electronic components. In this case, a plurality of adhesive members are used to adhere a plurality of components to each other, and various problems arise as the number of adhesive members increases.

### SUMMARY

An object of the present disclosure is to provide a semiconductor package with improved productivity.

An object of the present disclosure is to provide a semiconductor package with improved integration.

The problem to be solved by the present disclosure is not limited to the problems mentioned above, and other problems not mentioned will be clearly understood by those skilled in the art from the description below.

A semiconductor package according to some embodiments of the present disclosure may include a first redistribution substrate, a connection substrate disposed on the first redistribution substrate, wherein the connection substrate includes an opening extending through the connection substrate, a chip structure including a first semiconductor chip disposed in the opening of the connection substrate and on the first redistribution substrate, a first interposer substrate including a through electrode extending through the first interposer substrate disposed in the opening of the connection substrate and on the first redistribution substrate, wherein the first interposer substrate is horizontally spaced apart from the chip structure, a second semiconductor chip disposed on the first interposer substrate and electrically connected to the through electrode, a first molding layer on the chip structure, the first interposer substrate, and the second semiconductor chip in the opening of the connection substrate, and a second redistribution substrate on the first molding layer and the connection substrate, wherein a lower surface of the chip structure and a lower surface of the first interposer substrate are in electrical contact with an upper surface of the first redistribution substrate.

A semiconductor package according to some embodiments of the present disclosure may include a first redistribution substrate, a second redistribution substrate on the first redistribution substrate, a connection substrate between the first redistribution substrate and the second redistribution substrate, wherein the connection substrate includes an opening vertically penetrating an inside thereof, a first semiconductor chip and a chip stack on the first redistribution substrate, in the opening of the connection substrate, and horizontally spaced apart from each other, and a first molding layer covering the first semiconductor chip and the chip stack in the opening of the connection substrate, the chip stack may include a second semiconductor chip mounted on the first redistribution substrate and including a through electrode therein, a third semiconductor chip connected to the through electrode on the second semiconductor chip, and a second molding layer surrounding the third semiconductor chip on an upper surface of the second semiconductor chip, and a side surface of the second molding layer may be vertically aligned with a side surface of the second semiconductor chip.

A semiconductor package according to some embodiments of the present disclosure may include a first redistribution substrate having external connection terminals disposed on a lower surface thereof, a passive element disposed on the lower surface of the first redistribution substrate, between the external connection terminals, and spaced apart from the external connection terminals, a connection substrate disposed on the first redistribution substrate and having an opening penetrating an inside thereof, a first semiconductor chip provided in the opening of the connection substrate on the first redistribution substrate, a chip structure provided in the opening of the connection substrate, on the first redistribution substrate, horizontally spaced apart from the first semiconductor chip, and including an interposer substrate including a through electrode, a second semiconductor chip on the interposer substrate, and a first molding layer surrounding the second semiconductor chip on the interposer substrate, a second molding layer filling the opening of the connection substrate and covering the first semiconductor chip and the chip structure, a second redistribution substrate on the connection substrate and the second molding layer, a package substrate mounted on the second redistribution substrate through a substrate connection terminal, a third semiconductor chip mounted on the package substrate, and a third molding layer surrounding the third semiconductor chip on the package substrate, a lower surface of the first semiconductor chip and a lower surface of the chip structure may be in direct contact with the lower surface of the first redistribution substrate, and a side surface of the first molding layer may be vertically aligned with a side surface of the interposer substrate.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a cross-sectional view of a semiconductor package according to embodiments of the present disclosure.

FIG. 2 is a cross-sectional view of a semiconductor package according to embodiments of the present disclosure.

FIG. 3 is a cross-sectional view of a semiconductor package according to embodiments of the present disclosure.

FIG. 4 is a cross-sectional view of a semiconductor package according to embodiments of the present disclosure.

FIG. 5 is a cross-sectional view of a semiconductor package according to embodiments of the present disclosure.

FIGS. 6A, 6B, and 6C are cross-sectional views illustrating a method of manufacturing a chip structure according to embodiments of the present disclosure.

FIGS. 7 to 11 are cross-sectional views illustrating a method of manufacturing a semiconductor package according to embodiments of the present disclosure.

### DETAILED DESCRIPTION

Hereinafter, a semiconductor package according to the concept of the present disclosure will be described with reference to the drawings.

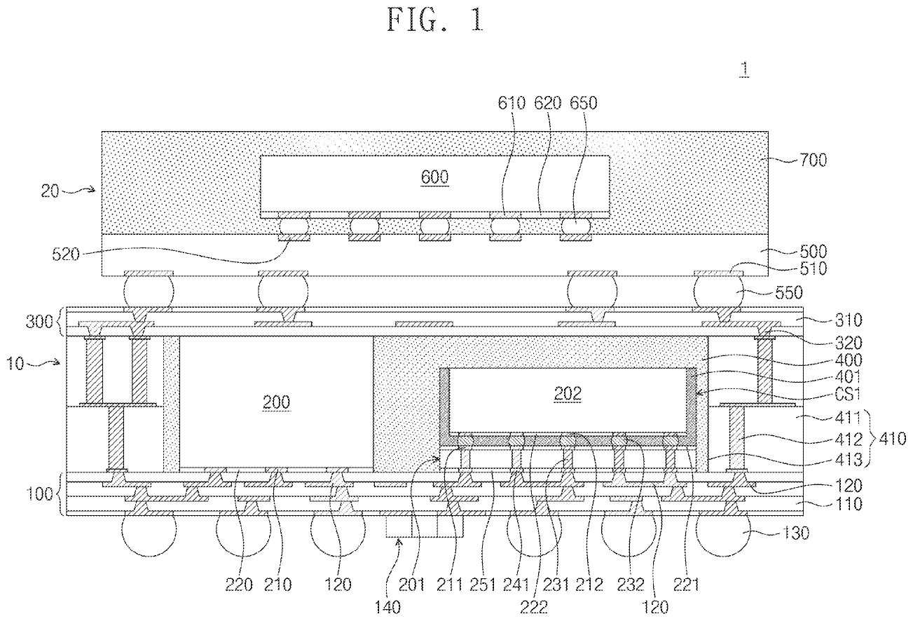

FIG. 1 is a cross-sectional view of a semiconductor package according to embodiments of the present disclosure.

Referring to FIG. 1, a semiconductor package 1 may include a lower package 10 and an upper package 20. The lower package 10 may include a first redistribution substrate 100, a first chip structure 200, a second chip structure CS1, a second redistribution substrate 300, a first molding layer 400, and a connection substrate 410.

The first redistribution substrate 100 may include one or more first insulating layers 110 and first wiring patterns 120 in the first insulating layers 110. Alternatively, the first redistribution substrate 100 may be a printed circuit board (PCB) including wiring patterns printed on upper and lower surfaces thereof. Hereinafter, the first redistribution substrate 100 will be described based on the embodiment illustrated in FIG. 1.

The first redistribution substrate 100 may include a plurality of first insulating layers 110 stacked on each other. According to FIG. 1, it is shown that four first insulating layers 110 are stacked, but the present disclosure is not limited thereto. The number of first insulating layers 110 provided in the first redistribution substrate 100 may be predetermined based on the design. The first insulating layers 110 may include, for example, a photo-imageable dielectric (PID) material, where the photo-imageable dielectric material may be a polymer. The photo-imageable dielectric material may include, for example, at least one of photosensitive polyimide, polybenzoxazole, phenol-based polymer, and benzocyclobutene-based polymer. In FIG. 1, an interface between each adjoining pair of the first insulating layers 110 is indicated, but the present disclosure is not limited thereto. According to other embodiments, interfaces between adjacent first insulating layers 110 may not be distinguishable.

Each of the first wiring patterns 120 may have a first via portion and a first wiring portion integrally connected to each other. The first wiring portion may be a wiring pattern for horizontal wiring within the first redistribution substrate 100. The first via portion may be a wiring pattern for vertical wiring within the first redistribution substrate 100. The first via portion may vertically connect the first wiring patterns 120 that are vertically adjacent to each other. The first via portion may have a narrower width toward an upper surface of the first redistribution substrate 100. The first via portion may be provided on the first wiring portion. The first wiring portion may be connected to the first via portion without a boundary. A width of the first wiring portion may be greater than a width of the first via portion. Each of the first wiring patterns 120 may have an upside down, T-shaped cross section. The first via portion of the first wiring patterns 120 may be disposed on an upper surface of a first insulating layer 110. The first via portions of the first wiring patterns 120 may be connected to the first wiring portions of other first wiring patterns 120 in adjoining first insulating layers 110 disposed thereon. Electrically connected/connected herein includes direct electrical connection/connection or indirect electrical connection/connection through another conductive component. The first wiring patterns 120 may include a conductive material, where for example, the first wiring patterns 120 may include copper.

The first wiring patterns 120 may further include seed patterns on upper surfaces of the first wiring patterns 120. The seed patterns may cover the upper surface and sidewall of the first via portion of the first wiring patterns 120 and the upper surface of the first wiring portion.

External connection terminals 130 may be disposed on lower surfaces of a lowermost first wiring pattern 120. The lowermost first wiring patterns 120 may function as pads on which external connection terminals 130 are disposed. The external connection terminals 130 may include solder balls or solder bumps. The external connection terminals 130 may include a conductive material, where for example, external connection terminals 130 may include tin, bismuth, lead, silver, or an alloy thereof.

In various embodiments, a passive element 140 may be provided on the lower surface of the first redistribution substrate 100, where the passive element 140 may be may be mounted on the same surface of the first redistribution substrate 100 as the external connection terminals 130. The passive elements 140 may be mounted on the lowermost first wiring patterns 120 in a lowermost first insulating layer 110. The passive element 140 may be disposed between the external connection terminals 130 on the lower surface of the first redistribution substrate 100. The passive element 140 may be spaced laterally from the external connection terminals 130. The passive element 140 may include, for example, a capacitor.

The connection substrate 410 may be provided on the first redistribution substrate 100. The connection substrate 410 may have a connection substrate opening 413 vertically penetrating the inside thereof. The connection substrate opening 413 may have an open hole shape connecting the upper and lower surfaces of the connection substrate 410. The connection substrate opening 413 may expose a portion of the upper surface of the first redistribution substrate 100. The first chip structure 200 and the second chip structure CS1 may be provided in the connection substrate opening 413 on the first redistribution substrate 100. The first molding layer 400 may be provided in the connection substrate opening 413 on the first redistribution substrate 100, where the first molding layer 400 may be around the first chip structure 200 and the second chip structure CS1. A lower surface of the connection substrate 410 may be in direct contact with the upper surface of the first redistribution substrate 100, where a lower surface of an insulating pattern 411 may be in direct contact with the upper surface of a first insulating layer 110. A side surface of the connection substrate 410 may be vertically aligned with a side surface of the first redistribution substrate 100 and a side surface of the second redistribution substrate 300 described later.

The connection substrate 410 may include an insulating pattern 411 and conductive patterns 412. The insulating pattern 411 may include, for example, an insulating material such as silicon nitride or silicon oxide.

The conductive patterns 412 may be provided in the insulating pattern 411, where the conductive patterns 412 may pass through the insulating pattern 411 between the connection substrate opening 413 and the side surface of the connection substrate 410. The conductive patterns 412 may be spaced apart from the connection substrate opening 413 and the side surface of the connection substrate 410. The conductive patterns 412 may be exposed on upper and lower surfaces of the insulating pattern 411 of the connection substrate 410. The conductive patterns 412 exposed on a lower surface of the insulating pattern 411 may be connected to the first wiring patterns 120.

As shown in FIG. 1, the connection substrate 410 can include a first layer of insulating pattern 411 including lower vias adjacent to the first redistribution substrate 100 and a second layer of insulating pattern 411 including upper vias on the first layer of insulating pattern 411, but the present disclosure is not limited thereto. Alternatively, the connection substrate 410 may be provided as a single layer or three or more layers as needed.

In various embodiments, a first chip structure 200 may be provided in the connection substrate opening 413 of the connection substrate 410, where the first chip structure 200 may be on the first redistribution substrate 100. The first chip structure 200 may be a chip structure composed of one semiconductor chip, where the first chip structure 200 may be a first semiconductor chip. Hereinafter, the first chip structure 200 will be referred to as a first semiconductor chip.

In various embodiments, the first semiconductor chip 200 may be spaced apart from an inner surface of the connection substrate 410 defining the connection substrate opening 413, where the first semiconductor chip 200 may be spaced apart from an inner surface of the insulating pattern 411. An upper surface of the first semiconductor chip 200 and the upper surface of the connection substrate 410 may be positioned at substantially the same vertical level from the upper surface of the first redistribution substrate 100, where the upper surface of the first semiconductor chip 200 and the upper surface of the connection substrate 410 can be coplanar. Alternatively, the upper surface of the first semiconductor chip 200 may be positioned at a lower vertical level than the upper surface of the connection substrate 410.

In various embodiments, the first semiconductor chip 200 may be, for example, a logic chip or a buffer chip. The logic chip may include an ASIC chip or an application processor (AP) chip. Alternatively, the logic chip may include a central processing unit (CPU) or a graphics processing unit (GPU). The ASIC chip may include an application specific integrated circuit (ASIC). In another embodiment, the first semiconductor chip 200 may be a memory chip.

The first semiconductor chip 200 may include first chip pads 210 provided on a lower surface thereof. The first chip pads 210 may be electrically connected to an integrated circuit formed in the first semiconductor chip 200. The first chip pads 210 may be exposed on the lower surface of the first semiconductor chip 200. The first chip pads 210 may include a conductive material, where the first chip pads 210 may include, for example, copper.

A first chip passivation layer 220 may be provided on the lower surface of the first semiconductor chip 200. The first chip passivation layer 220 may surround the first chip pads 210, where the first chip passivation layer 220 may expose lower surfaces of the first chip pads 210. The lower surface of the first chip passivation layer 220 and the lower surface of the first chip pads 210 may form a coplanar surface. The first chip passivation layer 220 may include an insulating material, such as silicon oxide, silicon nitride, or silicon carbonitride.

The first semiconductor chip 200 may be disposed on the first redistribution substrate 100 in a face down manner. The first semiconductor chip 200 may have a front surface facing the first redistribution substrate 100 and a rear surface opposite the front surface with a thickness therebetween. Hereinafter, in the present specification, the front surface of a semiconductor chip may be one side of an active surface on which integrated elements are formed in a semiconductor chip, and may be a surface on which pads of the semiconductor chip are formed, and the rear surface of the semiconductor chip may be a surface opposite to the front surface. That is, the lower surface of the first semiconductor chip 200 on which the first chip pads 210 are disposed may correspond to the front surface, and the upper surface of the first semiconductor chip 200 may correspond to the rear surface. For example, the first semiconductor chip 200 may be disposed so that the front surface thereof faces the first redistribution substrate 100. The first semiconductor chip 200 may be mounted on the first redistribution substrate 100. For example, as shown in FIG. 1, the lower surface of the first semiconductor chip 200 and the upper surface of the first redistribution substrate 100 may be in direct contact with each other. In this case, the first chip passivation layer 220 may be in direct contact with the first insulating layer 110 at the upper surface of the first redistribution substrate 100, and the first chip pads 210 and the first wiring patterns 120 may be directly connected to each other.

The second chip structure CS1 may be provided in the connection substrate opening 413 on the first redistribution substrate 100. The second chip structure CS1 may be spaced apart from an inner surface of the connection substrate 410. The second chip structure CS1 may be horizontally spaced apart from the first semiconductor chip 200 on the first redistribution substrate 100.

The second chip structure CS1 may include an interposer substrate 201, a second semiconductor chip 202, and a second molding layer 401. The second chip structure CS1 may be a chip structure including a substrate and a semiconductor chip mounted on the substrate. A first interposer substrate 201 may be disposed in an opening 413 of the connection substrate 410 on the first redistribution substrate 100.

In various embodiments, the interposer substrate 201 may be provided on the first redistribution substrate 100. A lower surface of the interposer substrate 201 may be in direct contact with an upper surface of the first redistribution substrate 100. That is, a lower surface of the second chip structure CS1 may be in direct contact with the upper surface of the first redistribution substrate 100. A thickness of the interposer substrate 201 may be less than a thickness of the first semiconductor chip 200. Accordingly, an upper surface of the interposer substrate 201 may be positioned at a lower vertical level from the upper surface of the first redistribution substrate 100 than the upper surface of the first semiconductor chip 200. The interposer substrate 201 may include, for example, a silicon interposer.

Upper pads 211 may be provided on the upper surface of the interposer substrate 201, where the upper pads 211 may be exposed on the upper surface of the interposer substrate 201. The upper pads 211 may include, for example, a conductive material, such as copper, nickel, or aluminum.

An upper protective layer 221 may be provided on the upper surface of the interposer substrate 201. The upper protective layer 221 may surround upper pads 211 on the upper surface of the interposer substrate 201. An upper surface of the upper protective layer 221 may expose upper surfaces of the upper pads 211. The upper surface of the upper protective layer 221 may be coplanar with the upper surface of the upper pads 211. The upper protective layer 221 may include, for example, an insulating material, such as silicon oxide, silicon nitride, or silicon carbonitride.

Lower pads 241 may be provided on the lower surface of the interposer substrate 201. The lower pads 241 may be exposed on the lower surface of the interposer substrate 201. The lower pads 241 may be connected to the first wiring patterns 120 of the first redistribution substrate 100. The lower pads 241 may include, for example, a conductive material such as copper, nickel, or aluminum.

A lower protective layer 251 may be provided on the lower surface of the interposer substrate 201. The lower protective layer 251 may surround the lower pads 241 on the lower surface of the interposer substrate 201. A lower surface of the lower protective layer 251 may expose lower surfaces of the lower pads 241. The lower surface of the protective layer 251 may be in direct contact with the upper surface of the first redistribution substrate 100. The lower protective layer 251 may include, for example, an insulating material, such as silicon oxide, silicon nitride, or silicon carbonitride.

Through electrodes 231 may be provided in the interposer substrate 201. The through electrodes 231 may extend through the interposer substrate 201. The through electrodes 231 may be between the upper pads 211 and the lower pads 241, and physically and electrically connect the upper pads 211 to the corresponding lower pads 241. The through electrodes 231 may be electrically connected to upper pads 211 and lower pads 241. The through electrodes 231 may include, for example, a conductive material, such as copper.

In various embodiments, a wiring layer or wiring pattern for connecting the upper pads 211 and the through electrodes 231 may be provided between the interposer substrate 201 and the upper protective layer 221. Alternatively, a wiring layer or wiring pattern for connecting the lower pads 241 and the through electrodes 231 may be provided between the interposer substrate 201 and the lower protective layer 251.

In another embodiment, the interposer substrate 201 may be a semiconductor chip including a circuit layer provided on a lower surface thereof. For example, the circuit layer may include an insulating layer, a wiring layer within the insulating layer, and a direct element electrically connected to the wiring layer. The circuit layer may be electrically connected to the through electrodes 231 and the lower pads 241. In this case, the second chip structure CS1 may be a chip stack in which semiconductor chips are stacked. An upper surface of the semiconductor chip may be positioned at a vertical level lower than an upper surface of the first semiconductor chip 200 from the upper surface of the first redistribution substrate 100. A lower surface of the semiconductor chip may be in direct contact with the upper surface of the first redistribution substrate. The semiconductor chip may include, for example, a logic chip.

In various embodiments, the second semiconductor chip 202 may be provided on the interposer substrate 201. The second semiconductor chip 202 may include a logic chip or a memory chip.

The second semiconductor chip 202 may include second chip pads 212 provided on a lower surface of the second semiconductor chip 202. The second chip pads 212 may be electrically connected to an integrated circuit formed in the second semiconductor chip 202. The second chip pads 212 may be exposed on the lower surface of the second semiconductor chip 202. The second chip pads 212 may include a conductive material, where for example, the second chip pads 212 may include copper, nickel, or aluminum.

A second chip passivation layer 222 may be provided on the lower surface of the second semiconductor chip 202. The second chip passivation layer 222 may surround the second chip pads 212, where the second chip passivation layer 222 may expose lower surfaces of the second chip pads 212. The lower surface of the second chip passivation layer 222 and the lower surfaces of the second chip pads 212 may form a coplanar surface. The second chip passivation layer 222 may include an insulating material, such as silicon oxide, silicon nitride, or silicon carbonitride.

In various embodiments, the second semiconductor chip 202 may be mounted on the interposer substrate 201, where for example, the second semiconductor chip 202 may be mounted on the interposer substrate 201 in a flip chip manner. In detail, first chip connection terminals 232 may be provided between the corresponding second chip pads 212 and the upper pads 211 of the interposer substrate 201, respectively. The first chip connection terminals 232 may be connected to the second chip pads 212 and the upper pads 211. The second semiconductor chip 202 may be connected to the through electrodes 231 through the first chip connection terminals 232. The first chip connection terminals 232 may include solder balls or solder bumps. The first chip connection terminals 232 may include, for example, tin, bismuth, lead, silver, or an alloy thereof. However, the present disclosure is not limited thereto, and the second semiconductor chip 202 may be mounted on the interposer substrate 201 in various mounting manners.

In various embodiments, the second molding layer 401 may surround the second semiconductor chip 202 on the interposer substrate 201. The second molding layer 401 may surround the first chip connection terminals 232 between the interposer substrate 201 and the second semiconductor chip 202 and fill the space between the first chip connection terminals 232. A side surface of the second molding layer 401 may be vertically aligned with a side surface of the interposer substrate 201. An upper surface of the second molding layer 401 may be coplanar with an upper surface of the second semiconductor chip 202. Alternatively, the upper surface of the second molding layer 401 may cover the upper surface of the second semiconductor chip 202. The second molding layer 401 may include an insulating polymer, such as an epoxy molding compound.

The first molding layer 400 may be provided in the connection substrate opening 413 between connection substrates 410 on the first redistribution substrate 100. The first molding layer 400 may surround the side surface of the first semiconductor chip 200 in the connection substrate opening 413 and bury the second chip structure CS1 therein. An upper surface of the first molding layer 400 may be coplanar with an upper surface of the connection substrate 410 and the upper surface of the first semiconductor chip 200. Alternatively, the first molding layer 400 may cover the upper surface of the first semiconductor chip 200. The first molding layer 400 may include an insulating polymer, such as an epoxy molding compound.

In various embodiments, the second redistribution substrate 300 may be provided on the connection substrate 410 and the first molding layer 400. The second redistribution substrate 300 may cover the connection substrate 410 and the first molding layer 400, and may be in contact with the upper surface of the connection substrate 410 and the upper surface of the first molding layer 400. When the upper surface of the first semiconductor chip 200 is exposed on the upper surface of the first molding layer 400, the second redistribution substrate 300 may be in contact with the upper surface of the connection substrate 410, the upper surface of the first semiconductor chip 200, and the upper surface and the upper surface of the first molding layer 400. The second redistribution substrate 300 may include one or more second insulating layers 310 and second wiring patterns 320 in each of the one or more second insulating layers 310.

In various embodiments, the second redistribution substrate 300 may include a plurality of second insulating layers 310 stacked on each other. Although FIG. 1 shows that three second insulating layers 310 are provided in the second redistribution substrate 300, the present disclosure is not limited thereto. The number of second insulating layers 310 provided in the second redistribution substrate 300 may be predetermined based on the design. The second insulating layers 310 may include, for example, a photo-imageable dielectric (PID) material, where the photo-imageable dielectric material may be a polymer. The photo-imageable dielectric material may include, for example, at least one of photosensitive polyimide, polybenzoxazole, phenol-based polymer, and benzocyclobutene-based polymer. In FIG. 1, an interface between the second insulating layers 310 is indicated, but the present disclosure is not limited thereto. According to other embodiments, interfaces between adjacent second insulating layers 310 may not be distinguishable.

In various embodiments, the second wiring patterns 320 may be provided in the second insulating layers 310. The uppermost second wiring patterns 320 among the second wiring patterns 320 may be exposed on the upper surface of the second redistribution substrate 300. Lowermost second wiring patterns 320 among the second wiring patterns 320 may be exposed on the lower surface of the second redistribution substrate 300. The lowermost second wiring patterns 320 may be connected to the conductive patterns 412 exposed on the upper surface of the connection substrate 410.

In various embodiments, each of the second wiring patterns 320 may have a second via portion and a second wiring portion integrally connected to each other. The second wiring portion may be a wiring pattern for horizontal wiring within the second redistribution substrate 300. The second via portion may be a wiring pattern for vertical wiring in the second insulating layers 310. The second via portion may vertically connect the second wiring patterns 320 adjacent to each other vertically. The second wiring portion may be provided on the second via portion. The second wiring portion may be physically and electrically connected to the second via portion without a boundary. A width of the second wiring portion may be greater than a width of the second via portion, where each of the second wiring patterns 320 may have a T-shaped cross section. The second wiring portions of the second wiring patterns 320 may be positioned on upper surfaces of the second insulating layers 310, respectively. The second via portion of the second wiring patterns 320 may pass through the second insulating layers 310 and be electrically connected to the second wiring portions of other second wiring patterns 320 disposed thereunder. The second wiring patterns 320 may include a conductive material, where for example, the second wiring patterns 320 may include copper.

The upper package 20 may be provided on the lower package 10. The upper package 20 may include a package substrate 500, a third semiconductor chip 600, and a third molding layer 700.

In various embodiments, the package substrate 500 may be a redistribution substrate including an insulating layer and a wiring pattern in the insulating layer. Alternatively, the package substrate 500 may be a printed circuit board having wiring patterns printed on upper and lower surfaces thereof.

First substrate pads 520 may be disposed on an upper surface of the package substrate 500. Upper surfaces of the first substrate pads 520 may be exposed on the upper surface of the package substrate 500. Second substrate pads 510 may be disposed on a lower surface of the package substrate 500, where the second substrate pads 510 may be electrically connected to the first substrate pads 520. Lower surfaces of the second substrate pads 510 may be exposed on a lower surface of the package substrate 500. The first substrate pads 520 and the second substrate pads 510 may be electrically connected through a wiring in the package substrate 500.

Substrate connection terminals 550 may be provided between the package substrate 500 and the second redistribution substrate 300. The substrate connection terminals 550 may be physically and electrically connected to the second substrate pad 510 and the second wiring patterns 320. The upper package 20 and the lower package 10 may be electrically connected through the substrate connection terminals 550.

The third semiconductor chip 600 may be provided on the package substrate 500. The third semiconductor chip 600 may have third chip pads 610 provided on a lower surface of the third semiconductor chip 600. The third chip pads 610 may be electrically connected to an integrated circuit formed in the third semiconductor chip 600. The third chip pads 610 may include a conductive material, where for example, the third chip pads 610 may include copper, nickel, or aluminum.

In various embodiments, a third chip passivation layer 620 may be provided on a lower surface of the third semiconductor chip 600. The third chip passivation layer 620 may surround the third chip pads 610, where the third chip passivation layer 620 may expose lower surfaces of the third chip pads 610. A lower surface of the third chip passivation layer 620 and the lower surface of the third chip pads 610 may form a coplanar surface. The third chip passivation layer 620 may include an insulating material, such as silicon oxide, silicon nitride, or silicon carbonitride.

In various embodiments, the third semiconductor chip 600 may be mounted in a flip chip manner. Third chip connection terminals 650 may be provided between the third semiconductor chip 600 and the package substrate 500, where the third chip connection terminals 650 may be disposed between the third chip pads 610 and the first substrate pad 520. The third chip connection terminals 650 may be physically and electrically connected to the third chip pads 610 and the first substrate pad 520. Accordingly, the third semiconductor chip 600 may be electrically connected to the lower package 10 through the package substrate 500. The third chip connection terminals 650 may include solder balls or solder bumps. The third chip connection terminals 650 may include, for example, tin, bismuth, lead, silver, or an alloy thereof. In another embodiment, the third semiconductor chip 600 may be mounted on the package substrate 500 by bonding wire.

The third molding layer 700 may be provided on the package substrate 500. The third molding layer 700 may cover the third semiconductor chip 600 on the upper surface of the package substrate 500. The third molding layer 700 may surround the third chip connection terminals 650 between the package substrate 500 and the third semiconductor chip 600. Alternatively, an underfill surrounding the third chip connection terminals 650 may be provided between the package substrate 500 and the third semiconductor chip 600. The third molding layer 700 may include an insulating polymer such as an epoxy-based molding compound.

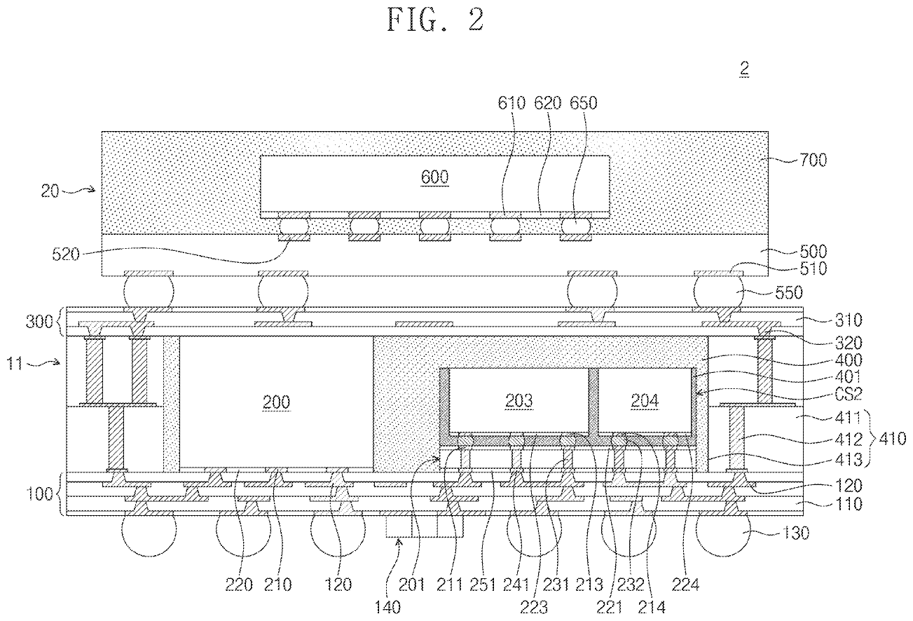

FIG. 2 is a cross-sectional view of a semiconductor package according to embodiments of the present disclosure. Aspects similar to those described above may be omitted, and the same reference numerals may be provided to the same configuration.

Referring to FIG. 2, a semiconductor package 2 may include an upper package 20 and a lower package 11. The upper package 20 may be substantially the same as that described with reference to FIG. 1. Unlike the embodiment of FIG. 1, the lower package 11 may include a plurality of semiconductor chips 203, 204 horizontally spaced apart on the interposer substrate 201. The lower package 11 may include the first semiconductor chip 200 provided in the connection substrate opening 413 on the first redistribution substrate 100 and a third chip structure CS2 horizontally spaced apart from the first semiconductor chip 200. The third chip structure CS2 may include an interposer substrate 201, a fourth semiconductor chip 203, a fifth semiconductor chip 204, and a second molding layer 401.

The interposer substrate 201 may be substantially the same as that described with reference to FIG. 1. In an embodiment, the interposer substrate 201 may be a semiconductor chip including a circuit layer provided on a lower surface of the interposer substrate 201. For example, the circuit layer may include an insulating layer, a circuit layer within the insulating layer, and a direct element electrically connected to the circuit layer. The circuit layer may be electrically connected to the through electrodes 231 and the lower pads 241. The interposer substrate 201 may constitute a chip stack with a fourth semiconductor chip 203 and a fifth semiconductor chip 204 to be described later.

In various embodiments, the fourth semiconductor chip 203 and the fifth semiconductor chip 204 may be provided on the interposer substrate 201. The fourth semiconductor chip 203 and the fifth semiconductor chip 204 may be horizontally spaced apart from each other on the interposer substrate 201. The fourth semiconductor chip 203 may include fourth chip pads 213 and a fourth chip passivation layer 223 on a lower surface thereof. The fifth semiconductor chip 204 may include fifth chip pads 214 and a fifth chip passivation layer 224 on a lower surface thereof. The fourth chip pads 213 and the fourth chip passivation layer 223 of the fourth semiconductor chip 203 and the fifth chip pads 214 and the fifth chip passivation layer 224 of the fifth semiconductor chip 204 may be substantially the same as the second chip pads 212 and the second chip passivation layer 222 of the second semiconductor chip 202 described with reference to FIG. 1. For example, the fourth semiconductor chip 203 may include a logic chip, and the fifth semiconductor chip 204 may include a memory chip.

The second molding layer 401 may surround side surfaces of the fourth semiconductor chip 203 and the fifth semiconductor chip 204 on the interposer substrate 201. The second molding layer 401 may expose upper surfaces of the fourth semiconductor chip 203 and the fifth semiconductor chip 204. In another embodiment, the second molding layer 401 may cover the upper surface of the fourth semiconductor chip 203 and/or the upper surface of the fifth semiconductor chip 204. A side surface of the second molding layer 401 may be vertically aligned with a side surface of the interposer substrate 201. The second molding layer 401 may include an insulating polymer such as an epoxy molding compound.

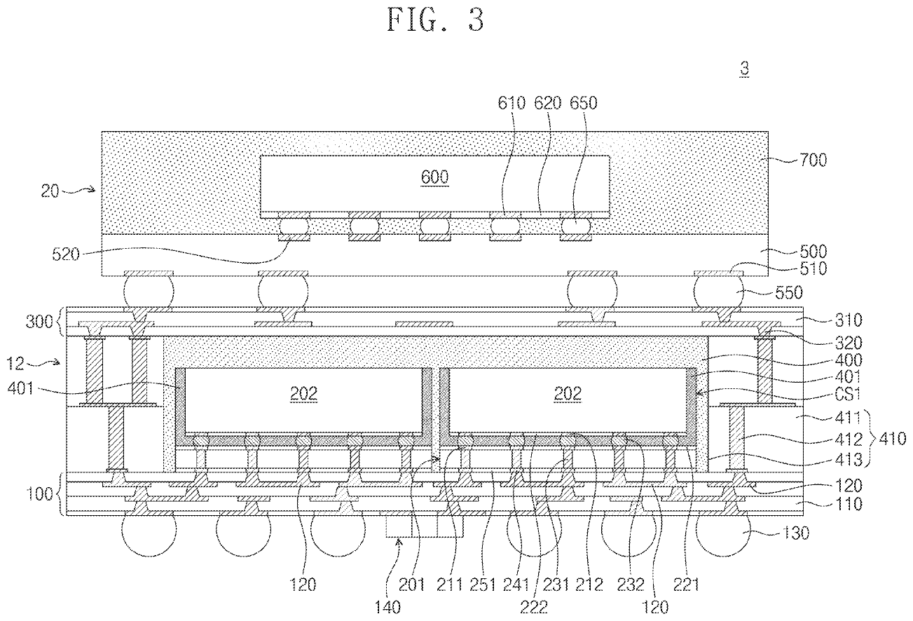

FIG. 3 is a cross-sectional view of a semiconductor package according to embodiments of the present disclosure. Aspects similar to those described above may be omitted, and the same reference numerals may be provided to the same configuration.

Referring to FIG. 3, a semiconductor package 3 may include an upper package 20 and a lower package 12. The upper package 20 may be substantially the same as that described with reference to FIG. 1. Unlike the lower package 10 described with reference to FIG. 1, the lower package 12 may have a second chip structure CS1 instead of the first semiconductor chip 200. Accordingly, the lower package 12 may include a plurality of second chip structures CS1 horizontally spaced apart from each other within the connection substrate opening 413 on the first redistribution substrate 100. A configuration of the second chip structures CS1 may be substantially the same as that described with reference to FIG. 1.

In various embodiments, the lower package 12 may further include an interposer substrate 201 disposed between each of the second semiconductor chips 202 and the first redistribution substrate 100, and a molding layer 401 separately surrounding each of the second semiconductor chips 202 on the respective interposer substrates 201.

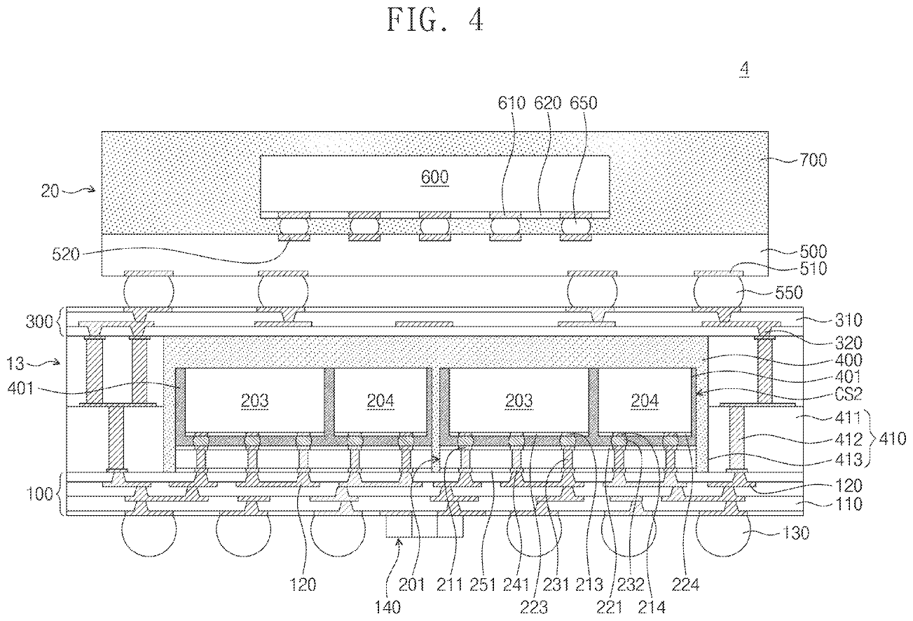

FIG. 4 is a cross-sectional view of a semiconductor package according to embodiments of the present disclosure. Aspects similar to those described above may be omitted, and the same reference numerals may be provided to the same configuration.

Referring to FIG. 4, a semiconductor package 4 may include an upper package 20 and a lower package 13. The upper package 20 may be substantially the same as that described with reference to FIG. 1. In the lower package 13, a third chip structure CS2 may be disposed instead of the first semiconductor chip 200 in the lower package 11 described with reference to FIG. 2. Accordingly, the lower package 13 may include a plurality of third chip structures CS2 horizontally spaced apart from each other within the connection substrate opening 413 on the first redistribution substrate 100. A configuration of each of the third chip structures CS2 may be substantially the same as that described with reference to FIG. 2.

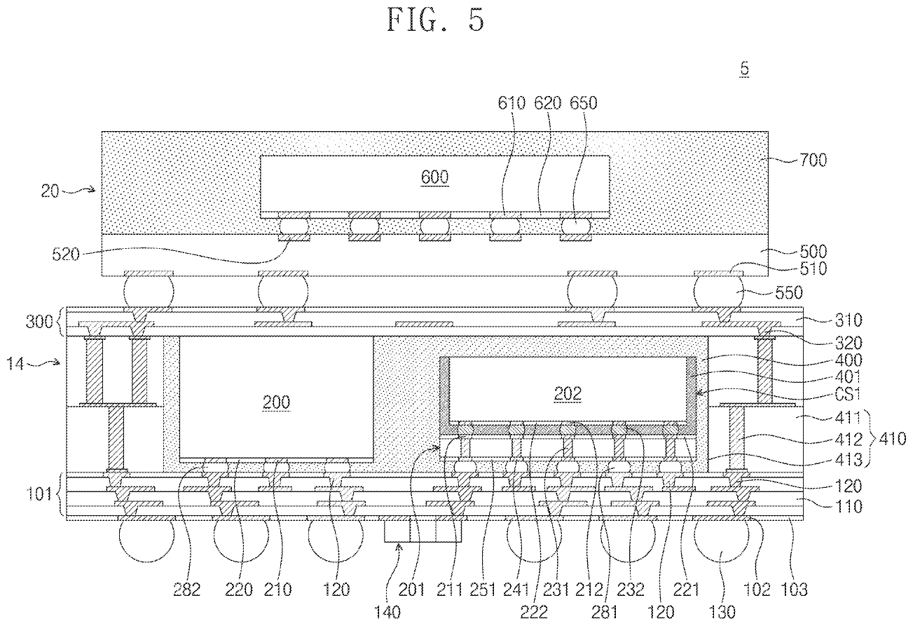

FIG. 5 is a cross-sectional view of a semiconductor package according to embodiments. Contents overlapping with those described above will be omitted, and the same reference numerals may be provided to the same configuration.

Referring to FIG. 5, a semiconductor package 5 may include an upper package 20 and a lower package 14. The upper package 20 may be substantially the same as that described with reference to FIG. 1. The lower package 14 may be different from the lower package 10 of FIG. 1 in configuration and the mounting manner of the connection substrate 410, the first semiconductor chip 200, and the second chip structure CS1 on the first redistribution substrate 101.

In various embodiments, redistribution pads 102 may be provided on a lower surface of the first redistribution substrate 101, where lower surfaces of the redistribution pads 102 may be exposed on the lower surface of the first redistribution substrate 101. The redistribution pads 102 may include a conductive material, such as copper, nickel, and aluminum.

A protective layer 103 may be provided on the lower surface of the first redistribution substrate 101. The protective layer 103 may surround the redistribution pads 102, where the lower surfaces of the redistribution pads 102 may be exposed on a lower surface of the protective layer 103.

External connection terminals 130 may be provided on the lower surface of the first redistribution substrate 101. The external connection terminals 130 may be disposed on the lower surfaces of the redistribution pads 102, respectively.

The first redistribution substrate 101 may include a plurality of first insulating layers 110 stacked on each other. As shown in FIG. 5, three first insulating layers 110 are included in the first redistribution substrate 101, but the number of first insulating layers 110 may be various according to need. A material constituting the first insulating layers 110 may be the same as the material constituting the first insulating layers 110 described with reference to FIG. 1.

A first wiring pattern 120 may be provided in the first insulating layers 110. The first wiring pattern 120 may include a first via portion and a first wiring portion integrally connected to each other. The first wiring portion may be a wiring pattern for horizontal wiring within the first redistribution substrate 101. The first via portion may be a wiring pattern for vertical wiring in the first insulating layers 110. The first wiring portions of the first wiring patterns 120 may be positioned on upper surfaces of the first insulating layers 110. The first via portions of the first wiring patterns 121 may pass through the first insulating layers 110 and be connected to the first wiring portions of other first wiring patterns 120 disposed thereunder. Each of the first wiring patterns 120 may have a T-shaped cross section. For example, the first wiring patterns 120 may include a conductive material, such as copper.

The first semiconductor chip 200 may be mounted on the first redistribution substrate 101 through first connection bumps 282. In detail, the first connection bumps 282 may be provided between the corresponding first wiring patterns 120 and the first chip pads 210 of the first semiconductor chip 200. The first connection bumps 282 may be connected to the first wiring patterns 120 and the first chip pads 210.

The second chip structure CS1 may be mounted on the first redistribution substrate 101 through second connection bumps 281. The second connection bumps 281 may be provided between the lower pads 241 of the interposer substrate 201 of the second chip structure CS1 and the first wiring patterns 120. The second connection bumps 281 may be connected to the lower pads 241 and the first wiring patterns 120, respectively.

A first molding layer 400 may surround the first connection bumps 282 between the first redistribution substrate 101 and the first semiconductor chip 200. Alternatively, an underfill filling between the first connection bumps 282 between the first redistribution substrate 101 and the first semiconductor chip 200 may be provided.

The first molding layer 400 may surround the second connection bumps 281 between the first redistribution substrate 101 and the second chip structure CS1. Alternatively, an underfill filling between the first redistribution substrate 101 and the second chip structure CS1 and surrounding the second connection bumps 281 may be provided.

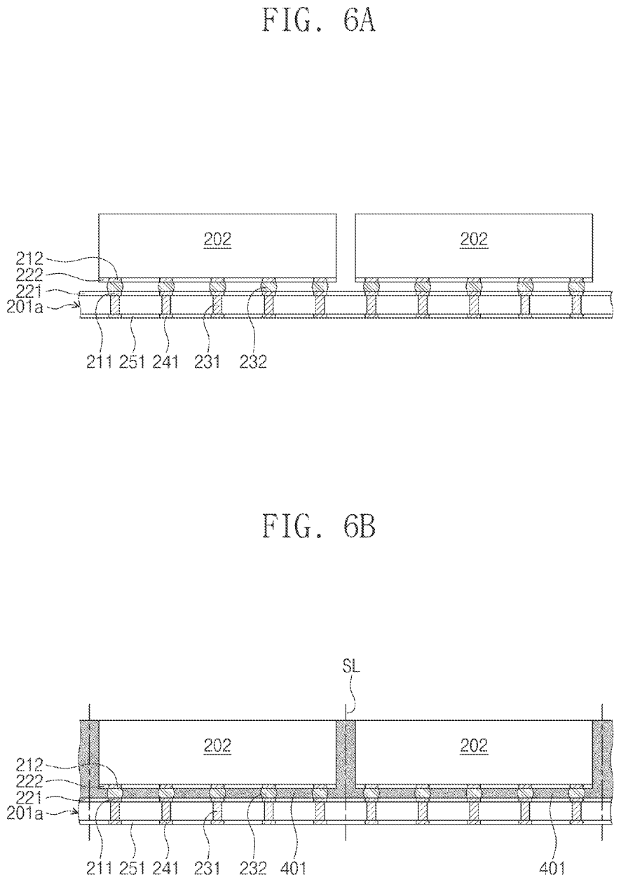

FIGS. 6A, 6B, and 6C are cross-sectional views illustrating a method of manufacturing a chip structure according to embodiments of the present disclosure.

Referring to FIG. 6A, an interposer substrate 201a may be provided to manufacture a second chip structure CS1. A configuration of the interposer substrate 201a may be substantially the same as that of the interposer substrate 201 described with reference to FIG. 1. However, the interposer substrate 201a may have a larger area than the interposer substrate 201 to manufacture a plurality of second chip structures CS1 by accommodating a plurality of semiconductor chips.

In various embodiments, second semiconductor chips 202 may be mounted on the interposer substrate 201a in a flip chip manner. For example, after providing first chip connection terminals 232 to second chip pads 212 of the second semiconductor chips 202, the second semiconductor chips 202 may be placed on the interposer substrate 201a, where the upper pads 211 of the interposer substrate 201a are aligned with the first chip connection terminals 232. Thereafter, a reflow process may be performed on the first chip connection terminals 232, so that one or more of the second semiconductor chips 202 may be mounted on the interposer substrate 201a.

Referring to FIG. 6B, a second molding layer 401 may be formed on the interposer substrate 201a, where the second molding layer 401 may be formed by applying an insulating material to cover the second semiconductor chips 202 on the upper surface of the interposer substrate 201a. The second molding layer 401 may surround the first chip connection terminals 232 between the interposer substrate 201a and the second semiconductor chips 202. Thereafter, a grinding process may be performed on an upper surface of the second molding layer 401 to remove a portion of the upper surface of the second molding layer 401 and expose upper surfaces of the second semiconductor chips 202. In various embodiments, a portion of the upper portions of the second semiconductor chips 202 may be removed together with a portion of the upper portion of the second molding layer 401. After forming the second molding layer 401 on the interposer substrate 201a, the interposer substrate 201a and the second molding layer 401 may be cut along a cutting line SL.

Referring to FIG. 6C, a second chip structure CS1 including one second semiconductor chip 202 may be manufactured through a cutting process. Through the cutting process, a side surface of the second molding layer 401 and a side surface of the interposer substrate 201 may be vertically aligned.

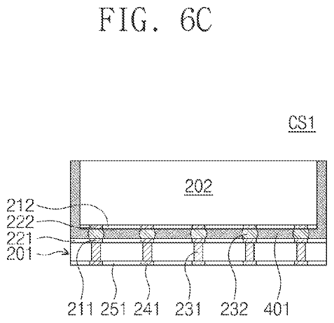

FIGS. 7 to 11 are cross-sectional views illustrating a method of manufacturing a semiconductor package, according to embodiments of the present disclosure.

Referring to FIG. 7, a connection substrate 410 may be provided on a front carrier substrate 1000. Before disposing the connection substrate 410 on the front carrier substrate 1000, a portion of the connection substrate 410 may be removed to form a connection substrate opening 413 extending through the connection substrate 410.

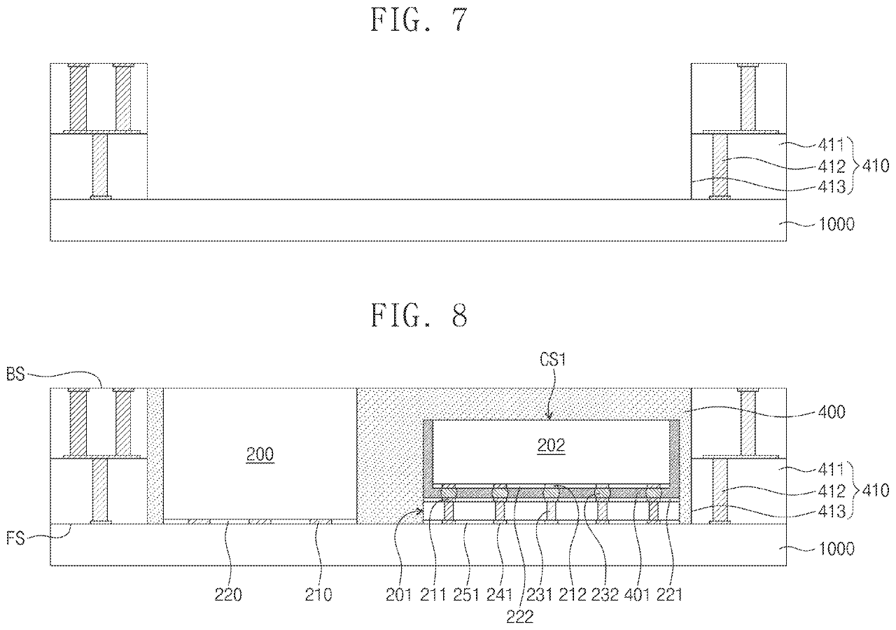

Referring to FIG. 8, a first semiconductor chip 200 and a second chip structure CS1 may be disposed in the connection substrate opening 413 on the front carrier substrate 1000. The first semiconductor chip 200 and the second chip structure CS1 may be spaced apart from an inner surface of the connection substrate 410. The first semiconductor chip 200 and the second chip structure CS1 may be horizontally spaced apart from each other. A front surface of the first semiconductor chip 200, which can be an active surface, may be disposed toward the carrier substrate 1000. The second chip structure CS1 may be disposed so that the interposer substrate 201 of the second chip structure CS1 faces the front carrier substrate 1000. The second chip structure CS1 may be tested before being disposed in the connection substrate opening 413, and only those without defects may be selected.

An insulating material may be applied in the connection substrate opening 413 to form a first molding layer 400 surrounding a side surface of the first semiconductor chip 200 and covering the second chip structure CS1. An upper surface of the first molding layer 400 may be coplanar with an upper surface of the connection substrate 410 and an upper surface of the first semiconductor chip 200. Alternatively, the first molding layer 400 may cover the upper surface of the first semiconductor chip 200. Accordingly, a preliminary package including the connection substrate 410, the first semiconductor chip 200, the second chip structure CS1, and the first molding layer 400 may be formed.

Hereinafter, a front surface FS of the preliminary package may be a surface adjacent to a front surface of the first semiconductor chip 200, and a rear surface BS of the preliminary package may be a surface adjacent to a rear surface of the first semiconductor chip 200.

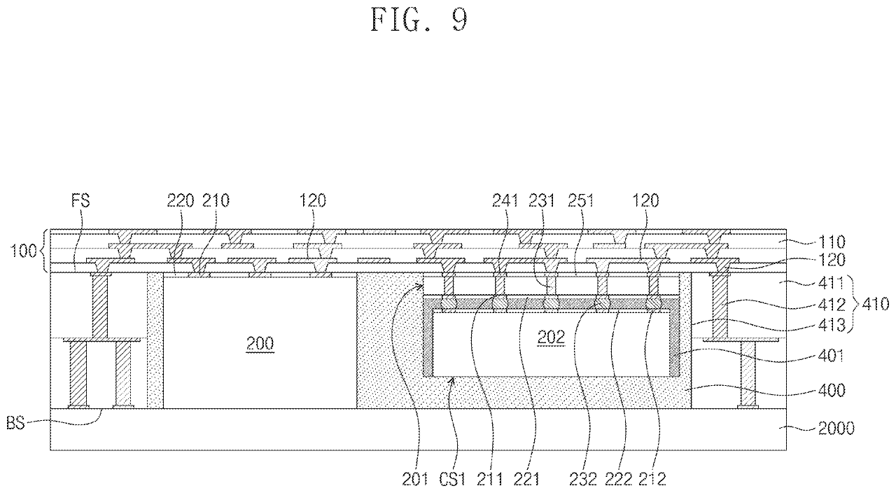

Referring to FIG. 9, a rear carrier substrate 2000 may be provided on the rear surface BS of the preliminary package, and the aforementioned front carrier substrate 1000 may be removed from the preliminary package. Accordingly, the front surface FS of the preliminary package may be exposed. A first redistribution substrate 100 may be formed on the front surface FS of the preliminary package. In various embodiments, an insulating material may be applied on the front surface FS of the preliminary package to form the first insulating layer 110. Openings may be formed by patterning the first insulating layer 110, where the openings may expose at least a portion of each of the conductive patterns 412, the first chip pads 210, and the lower pads 241. Afterwards, first wiring patterns 120 may be formed to fill the openings and cover a portion of the upper surface of the first insulating layer 110. The first redistribution substrate 100 may be manufactured by repeating forming the first insulating layer 110, patterning the first insulating layer 110, and forming the first wiring patterns 120, where a plurality of first insulating layers 110 can form a stack containing first wiring patterns 120.

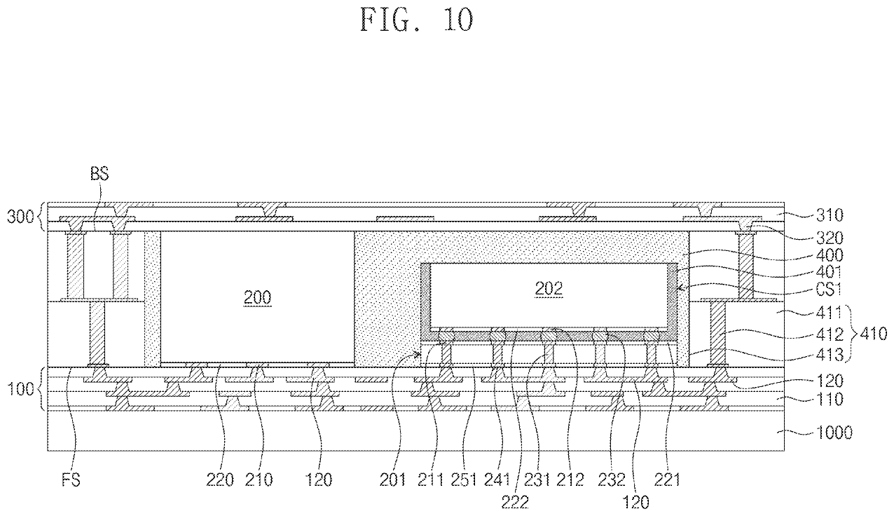

Referring to FIG. 10, a front carrier substrate 1000 may be attached to a lower surface of the first redistribution substrate 100, and the rear carrier substrate 2000 (refer to FIG. 9) may be removed. A second redistribution substrate 300 may be formed on the rear surface BS of the preliminary package. In various embodiments, an insulating material may be applied on the rear surface BS of the preliminary package to form a second insulating layer 310. Openings exposing at least a portion of the conductive patterns 412 may be formed by patterning the second insulating layer 310. Second wiring patterns 320 may be formed to fill the openings and cover a portion of the upper surface of the second insulating layer 310. The second redistribution substrate 300 may be formed by repeating forming the second insulating layer 310, patterning the second insulating layer 310, and forming the second wiring patterns 320, where a plurality of second insulating layers 310 can form a stack containing second wiring patterns 320.

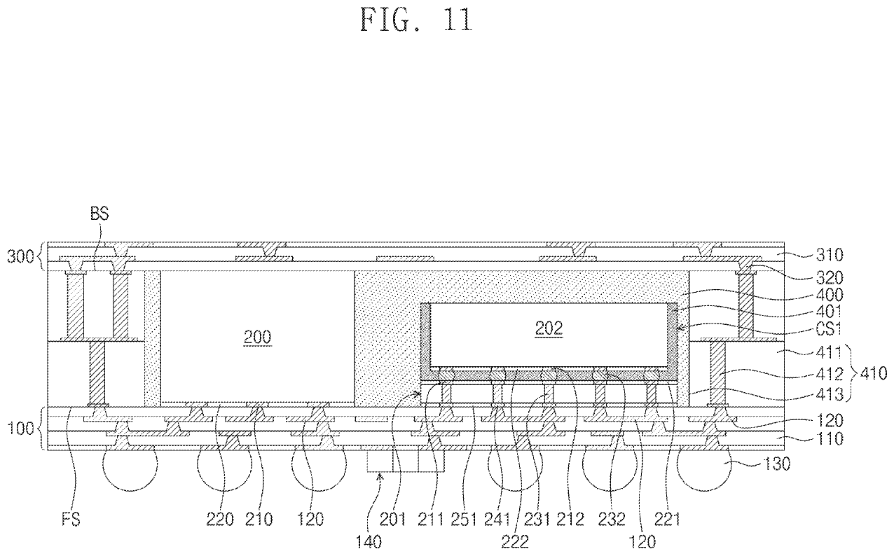

Referring to FIG. 11, the front carrier substrate 1000 of FIG. 10 may be removed, and external connection terminals 130 and a passive element 140 may be provided on the lower surface of the first redistribution substrate 100. The external connection terminals 130 and the passive element 140 may be disposed on the first wiring patterns 120 exposed on the lower surface of the first redistribution substrate 100. The passive element 140 may be disposed between the external connection terminals 130. The external connection terminals 130 and the passive element 140 may be spaced apart from each other.

Referring to FIG. 1 again, an upper package 20 may be provided on a lower package 10. The third semiconductor chip 600 may be mounted on the package substrate 500 in a flip chip manner. For example, after providing the third chip connection terminal 650 on the third chip pad 610 of the third semiconductor chip 600, the third semiconductor chip 600 may be disposed on the package substrate 500 such that the first substrate pad 520 of the package substrate 500 and the third chip connection terminal 650 are aligned. Thereafter, the third semiconductor chip 600 may be mounted on the package substrate 500 by performing a reflow process on the third chip connection terminal 650.

A third molding layer 700 may be formed on the package substrate 500. The third molding layer 700 may cover the third semiconductor chip 600 on an upper surface of the package substrate 500. Accordingly, the upper package 20 may be manufactured.

The upper package 20 may be mounted on the lower package 10. The upper package 20 may provide the substrate connection terminal 550 on the second substrate pad 510 of the package substrate 500, where the substrate connection terminal 550 may be disposed on the lower package 10 to be aligned with the second wiring patterns 320 exposed on the upper surface of the second redistribution substrate 300. Thereafter, the upper package 20 may be mounted on the lower package 10 by performing a reflow process on the substrate connection terminal 550.

In various embodiments, the semiconductor package according to embodiments may include the chip structure horizontally spaced apart from the semiconductor chip. After the chip structures are tested, those without defects may be selected and mounted on the redistribution substrate. Accordingly, the productivity of the semiconductor package may be improved. In addition, the chip structure including the plurality of semiconductor chips may be disposed between the redistribution substrates to improve the integration of the semiconductor package.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims.

What is claimed is:

1. A semiconductor package comprising:
a first redistribution substrate;
a connection substrate disposed on the first redistribution substrate, wherein the connection substrate includes an opening extending through the connection substrate;
a chip structure including a first semiconductor chip disposed in the opening of the connection substrate and on the first redistribution substrate;
a first interposer substrate including a through electrode extending through the first interposer substrate disposed in the opening of the connection substrate and on the first redistribution substrate, wherein the first interposer substrate is horizontally spaced apart from the chip structure;
a second semiconductor chip disposed on the first interposer substrate and electrically connected to the through electrode;
a first molding layer on the chip structure, the first interposer substrate, and the second semiconductor chip in the opening of the connection substrate; and
a second redistribution substrate on the first molding layer and the connection substrate,
wherein a lower surface of the chip structure and a lower surface of the first interposer substrate are in electrical contact with an upper surface of the first redistribution substrate.

2. The semiconductor package of claim 1, further comprising a second molding layer on the second semiconductor chip,
wherein a side surface of the second molding layer is vertically aligned with a side surface of the first interposer substrate.

3. The semiconductor package of claim 1, wherein the connection substrate includes an insulating pattern and conductive patterns inside the insulating pattern.

4. The semiconductor package of claim 1, wherein the first redistribution substrate includes an insulating layer and wiring patterns inside the insulating layer, and
wherein one of the wiring patterns exposed on the upper surface of the first redistribution substrate is electrically connected to a chip pad on the lower surface of the chip structure and a substrate pad on the lower surface of the first interposer substrate.

5. The semiconductor package of claim 1, wherein the chip structure includes:
a second interposer substrate disposed on the first redistribution substrate;
a first semiconductor chip mounted on the second interposer substrate; and
a third molding layer surrounding the first semiconductor chip on an upper surface of the second interposer substrate, and
wherein a side surface of the third molding layer is vertically aligned with a side surface of the second interposer substrate.

6. The semiconductor package of claim 1, wherein two or more of the second semiconductor chip is provided,
wherein the two or more second semiconductor chips are horizontally spaced apart from each other on the first interposer substrate, and
wherein the two or more second semiconductor chips include a logic chip or a memory chip.

7. The semiconductor package of claim 1, wherein the first interposer substrate includes a silicon interposer.

8. The semiconductor package of claim 1, further comprising an upper package mounted on the second redistribution substrate through a substrate connection terminal,
wherein the upper package includes:
a package substrate;
a fourth semiconductor chip mounted on the package substrate; and
a fourth molding layer on an upper surface of the package substrate and surrounding the fourth semiconductor chip.

9. A semiconductor package comprising:
a first redistribution substrate;
a second redistribution substrate on the first redistribution substrate;
a connection substrate between the first redistribution substrate and the second redistribution substrate, wherein the connection substrate includes an opening vertically penetrating an inside thereof;
a first semiconductor chip and a chip stack on the first redistribution substrate, in the opening of the connection substrate, and horizontally spaced apart from each other; and
a first molding layer covering the first semiconductor chip and the chip stack in the opening of the connection substrate,
wherein the chip stack includes:
a second semiconductor chip mounted on the first redistribution substrate and including a through electrode therein;
a third semiconductor chip connected to the through electrode on the second semiconductor chip; and
a second molding layer surrounding the third semiconductor chip on an upper surface of the second semiconductor chip, and
wherein a side surface of the second molding layer is vertically aligned with a side surface of the second semiconductor chip.

10. The semiconductor package of claim 9, wherein an upper surface of the first semiconductor chip is positioned at a vertical level higher than the upper surface of the second semiconductor chip.

11. The semiconductor package of claim 9, wherein a lower surface of the first semiconductor chip and a lower surface of the second semiconductor chip are in direct contact with an upper surface of the first redistribution substrate.

12. The semiconductor package of claim 9, wherein the connection substrate includes an insulating pattern and conductive patterns in the insulating pattern, and
wherein a side surface of the connection substrate is vertically aligned with a side surface of the first redistribution substrate and a side surface of the second redistribution substrate.

13. The semiconductor package of claim 9, wherein the second semiconductor chip includes a logic chip, and
wherein the third semiconductor chip includes a memory chip.

14. The semiconductor package of claim 9, further comprising:
an interposer substrate between the first semiconductor chip and the first redistribution substrate; and
a third molding layer surrounding the first semiconductor chip on an upper surface of the interposer substrate,
wherein a side surface of the third molding layer is vertically aligned with a side surface of the interposer substrate.

15. The semiconductor package of claim 9, wherein the first redistribution substrate includes an insulating layer and wiring patterns in the insulating layer, and
wherein the wiring patterns exposed on an upper surface of the first redistribution substrate are directly connected to first chip pads on a lower surface of the first semiconductor chip, second chip pads on a lower surface of the second semiconductor chip, and conductive patterns exposed on a lower surface of the insulating substrate.

16. The semiconductor package of claim 9, wherein the third semiconductor chip is provided in plural, and
wherein the third semiconductor chips are horizontally spaced apart from each other on the second semiconductor chip.

17. A semiconductor package comprising:
a first redistribution substrate having external connection terminals disposed on a lower surface thereof;
a passive element disposed on the lower surface of the first redistribution substrate, between the external connection terminals, and spaced apart from the external connection terminals;
a connection substrate disposed on the first redistribution substrate and having an opening penetrating an inside thereof;
a first semiconductor chip provided in the opening of the connection substrate on the first redistribution substrate;
a chip structure provided in the opening of the connection substrate, on the first redistribution substrate, horizontally spaced apart from the first semiconductor chip, and including an interposer substrate including a through electrode, a second semiconductor chip on the interposer substrate, and a first molding layer surrounding the second semiconductor chip on the interposer substrate;
a second molding layer filling the opening of the connection substrate and covering the first semiconductor chip and the chip structure;
a second redistribution substrate on the connection substrate and the second molding layer;
a package substrate mounted on the second redistribution substrate through a substrate connection terminal;
a third semiconductor chip mounted on the package substrate; and
a third molding layer surrounding the third semiconductor chip on the package substrate,
wherein a lower surface of the first semiconductor chip and a lower surface of the chip structure are in direct contact with the lower surface of the first redistribution substrate, and
wherein a side surface of the first molding layer is vertically aligned with a side surface of the interposer substrate.

18. The semiconductor package of claim 17, wherein the second semiconductor chip is provided in plural,
wherein the second semiconductor chips are horizontally spaced apart from each other, and
wherein the second semiconductor chips include a logic chip or a memory chip.

19. The semiconductor package of claim 17, wherein an upper surface of the first semiconductor chip is positioned at a higher vertical level than an upper surface of the chip structure.

20. The semiconductor package of claim 17, wherein the first redistribution substrate includes an insulating layer and a wiring pattern in the insulating layer,
wherein the wiring pattern includes:
a wiring portion extending onto an upper surface of the insulating layer; and
a via portion passing through the insulating layer and connected to the wiring portion,
wherein a width of the via portion narrows toward an upper surface of the first redistribution substrate.
